(19) United States
(12) Patent Application Publication
(10) Pub. No.: US 2026/0105957 A1
(43) Pub. Date: Apr. 16, 2026

(54) WRITING CIRCUIT

(71) Applicant: United Microelectronics Corp., Hsinchu (TW)

(72) Inventors: Chung-Hao Chen, Taoyuan City (TW); Cheng-Hsiao Lai, Chiayi County (TW)

(73) Assignee: United Microelectronics Corp., Hsinchu (TW)

(21) Appl. No.: 18/938,304

(22) Filed: Nov. 6, 2024

(30) Foreign Application Priority Data
Oct. 16, 2024 (TW) 113139297

(51) Int. Cl. G11C 13/00

(52) U.S. Cl. CPC G11C 13/0069; G11C 13/0038; G11C 13/0097; G11C 2013/0078

(57) ABSTRACT

A writing circuit includes a writing voltage generator, a reference voltage provider, and a comparison circuit. The writing voltage generator generates a writing voltage to perform a writing operation on each resistive memory cell among a resistive memory cell array. The reference voltage provider, during the writing operation, generates and provides a reference voltage according to a resistance of a reference device. The comparing circuit generates a comparison result by comparing the reference voltage with a target value. The writing voltage generator adjusts a maintenance time of the writing voltage according to the comparison result.

### CROSS-REFERENCE TO RELATED APPLICATION

This application claims the priority benefit of Taiwan application serial no. 113139297, filed on October 16, 2024. The entirety of the above-mentioned patent application is hereby incorporated by reference herein and made a part of this specification.

### BACKGROUND

### Technical Field

The disclosure relates to a writing circuit, and particularly relates to a data writing circuit for a resistive random access memory.

### Description of Related Art

In the related art, it is common to perform reset operations on multiple resistive memory cells of a resistive random access memory (RRAM) by the same writing time. Due to the different electrical characteristics of the resistive memory cells, performing reset operations on the resistive memory cells by the same writing time may result in a wider distribution of resistance values among the resistive memory cells. Consequently, the uniformity of the resistance of the resistive memory cells may be reduced. Furthermore, performing reset operations on the resistive memory cells with the same writing time may also lead to excessive reset of the resistive memory cells, thereby increasing the difficulty of performing set operations on excessively reset resistive memory cells.

### SUMMARY

The disclosure provides various writing circuits which can dynamically adjust the maintenance time of the applied writing voltage according to the electrical characteristics of the selected resistive memory cell.

A writing circuit of the disclosure includes a writing voltage generator, a reference voltage provider, and a comparison circuit. The writing voltage generator provides a writing voltage to each of multiple resistive memory cells among a resistive memory cell array to perform a writing operation. During the writing operation, the reference voltage provider generates and provides a reference voltage according to a resistance value of a reference element. The comparison circuit generates a comparison result by comparing the reference voltage with a target value. The writing voltage generator adjusts a maintenance time of the writing voltage according to the comparison result.

Another writing circuit of the disclosure includes a writing voltage generator and a comparison circuit. The writing voltage generator provides a writing voltage to each resistive memory cell among the resistive memory cell array to perform a writing operation. The comparison circuit generates a comparison result by comparing the voltage on the source line of each resistive memory cell with a threshold voltage. The writing voltage generator adjusts a maintenance time of the writing voltage according to the comparison result.

Based on the above, the writing circuit of the disclosure dynamically adjusts the maintenance time of the writing voltage provided to each of the resistive memory cells according to the comparison result generated by the comparison circuit. In this way, the bias intensity of the writing action for each of the resistive memory cells may be dynamically adjusted corresponding to its electrical characteristics. As a result, the uniformity of the resistance values of the resistive memory cells after the completion of the writing operation may be effectively improved, and the state of excessive reset (over reset) of the individual resistive memory cell may be effectively prevented.

### BRIEF DESCRIPTION OF THE DRAWINGS

FIG. 1 illustrates a schematic diagram of a writing circuit according to an embodiment of the disclosure.

FIG. 2 illustrates a schematic diagram of an adjustment action of a writing voltage according to an embodiment of the disclosure.

FIG. 3A illustrates a schematic diagram of another embodiment of a writing circuit of the disclosure.

FIG. 3B illustrates an action waveform diagram of the writing circuit in FIG. 3A.

FIG. 4 illustrates a circuit diagram of an implementation method of a pulse stopping generator according to an embodiment of the disclosure.

FIG. 5 illustrates a schematic diagram of another embodiment of a writing circuit of the disclosure.

FIG. 6A illustrates a schematic diagram of another embodiment of a writing circuit of the disclosure.

FIG. 6B illustrates an action waveform diagram of the embodiment of FIG. 6A of the disclosure.

### DESCRIPTION OF THE EMBODIMENTS

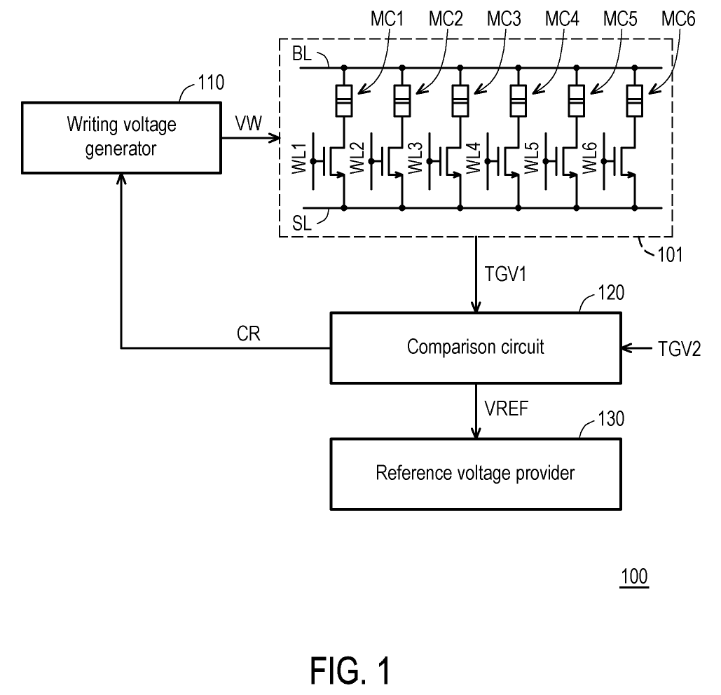

Referring to FIG. 1, FIG. 1 illustrates a schematic diagram of a writing circuit according to an embodiment of the disclosure. In this embodiment, a writing circuit 100 is configured to perform a writing operation on a resistive memory cell array 101. The resistive memory cell array 101 includes multiple resistive memory cells MC1 to MC6, where each of the resistive memory cells MC1 to MC6 may be a one-transistor-one-resistor (1T1R) memory cell. The resistive memory cells MC1 to MC6 are coupled in parallel between a bit line BL and a source line SL, and are respectively coupled to word lines WL1 to WL6. Further, the writing circuit 100 is configured to perform a writing operation on each of the resistive memory cells MC1 to MC6, and through the writing operation to reset the resistance value of each of the resistive memory cells MC1 to MC6 from a relatively low first resistance value to a relatively high second resistance value. In other words, the writing operation in this embodiment may be called a reset operation.

In this embodiment, the writing circuit 100 includes a writing voltage generator 110, a reference voltage provider 130, and a comparison circuit 120. The writing voltage generator 110 is coupled to the resistive memory cell array 101 and the comparison circuit 120. The writing voltage generator 110 is configured to provide a writing voltage VW to the resistive memory cell array 101, and to perform the writing operation on each of the resistive memory cells MC1 to MC6 among the resistive memory cell array 101, that is, to perform a resistance value reset operation on each of the resistive memory cells MC1 to MC6. Here, taking the resistive memory cell MC3 as an example of the selected resistive memory cell to perform the writing operation, the selected resistive memory cell MC3 may receive an activated word line signal through the word line WL3. Correspondingly, the writing voltage generator 110 provides the writing voltage VW to the bit line BL, so that the resistance value of the selected resistive memory cell MC3 is reset to a relatively high resistance value.

It is worth mentioning that the number of resistive memory cells MC1 to MC6 among the resistive memory cell array 101 in FIG. 1 is only an illustrative example and should not be used to limit the scope of the disclosure. The number of resistive memory cells among the resistive memory cell array 101 is not necessarily limited.

In this embodiment, the writing voltage VW may be a pulse voltage. The pulse voltage of the writing voltage VW may have a constant voltage level and a pulse width.

In this embodiment of the disclosure, the writing voltage generator 110 may receive a comparison result CR from the comparison circuit 120, and adjust the pulse width of the generated writing voltage VW according to the comparison result CR. The comparison circuit 120 is configured to compare a reference voltage VREF with target values TGV1 or TG2, and thereby generate the comparison result CR. The reference voltage VREF may be provided by the reference voltage provider 130. The reference voltage provider 130 may generate and provide the reference voltage VREF according to the resistance value of the reference component therein during the writing operation. In an embodiment of the disclosure, the comparison circuit 120 may receive the target value TGV1 from the resistive memory cell array 101, and generate the comparison result CR by comparing the reference voltage VREF with the target value TGV1. In another embodiment of the disclosure, the comparison circuit 120 may generate the comparison result CR by comparing the reference voltage VREF with an externally provided target value TGV2 from the resistive memory cell array 101.

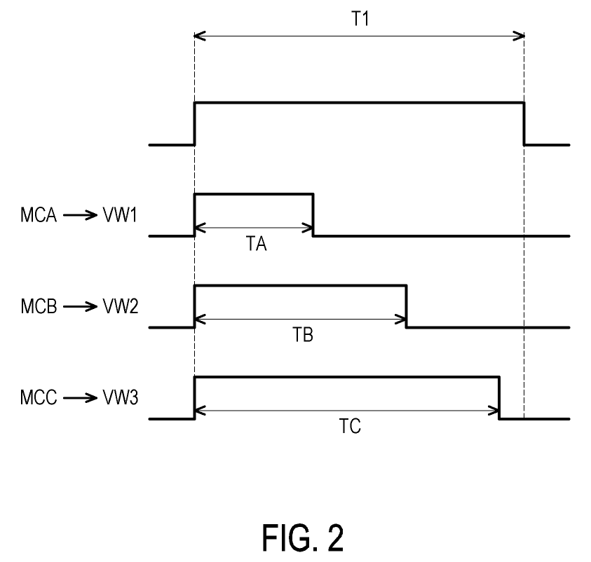

The following description refers to FIG. 2, where FIG. 2 illustrates a schematic diagram of an adjustment action of a writing voltage according to an embodiment of the disclosure. In FIG. 2, resistive memory cells MCA, MCB, and MCC have different electrical characteristics, where the resistive memory cell MCA has the fastest resistance value reset speed compared to the resistive memory cells MCB and MCC. The resistive memory cell MCC has the slowest resistance value reset speed compared to the resistive memory cells MCA and MCB. The writing voltage generator of this embodiment of the disclosure provides a writing voltage VW1 with a pulse width TA according to the received comparison signal during a time interval T1 when performing a writing operation on the resistive memory cell MCA, provides a writing voltage VW2 with a pulse width TB according to the received comparison signal during the time interval T1 when performing a writing operation on resistive memory cell MCB, and provides a writing voltage VW3 with a pulse width TC according to the received comparison signal during the time interval T1 when performing a writing operation on resistive memory cell MCC. Here, the pulse width TA is smaller than the pulse width TB, and the pulse width TB is smaller than the pulse width TC.

By dynamically adjusting the pulse width of the writing voltage, the resistive memory cells MCA to MCC may have substantially the same resistance value after completing the reset operation, which may effectively improve the uniformity of the resistance values of the resistive memory cells after reset, and reduce the possibility of excessive reset occurring in the resistive memory cells.

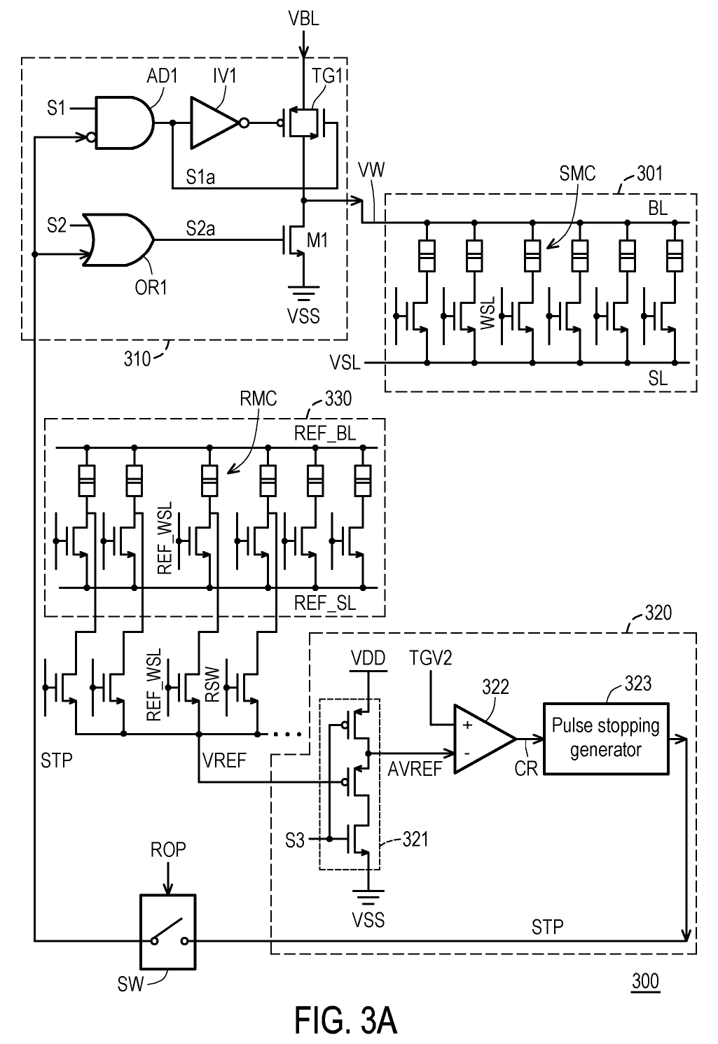

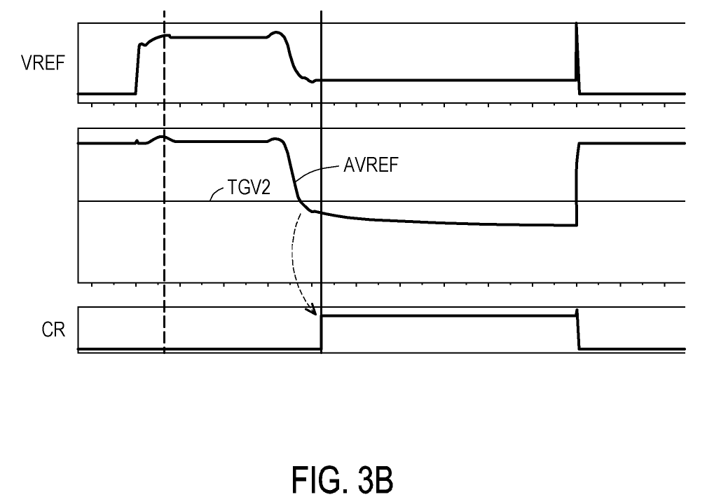

Referring to FIG. 3A and FIG. 3B together, FIG. 3A illustrates a schematic diagram of another embodiment of a writing circuit of the disclosure, and FIG. 3B illustrates an action waveform diagram of the writing circuit in FIG. 3A. In FIG. 3B, a vertical axis represents voltage, and a horizontal axis represents time. The writing circuit 300 includes a writing voltage generator 310, a reference voltage provider 320, and a comparison circuit 330. The writing voltage generator 310 is coupled to a resistive memory cell array 301 and is configured to provide the writing voltage VW to the bit line BL of the resistive memory cell array 301. The source line SL of the resistive memory cell array 301 receives a source voltage VSL.

The writing voltage generator 310 includes an AND gate AD1, an OR gate OR1, an inverter IV1, a transmission gate TG1, and a transistor M1. The AND gate AD1 receives a signal S1 and a stop pulse STP, and performs an AND logic on the signal S1 and the inverted signal of the stop pulse STP to generate a signal S1a. In conjunction with the inverter IV1, the writing voltage generator 310 may determine the conduction or cut-off state of the transmission gate TG1 according to the signal S1a. When the transmission gate TG1 is conducted, the transmission gate TG1 may generate the writing voltage VW according to the received voltage VBL, and transmit the writing voltage VW to the bit line BL of the resistive memory cell array 301. When the transmission gate TG1 is cut off, the transmission gate TG1 stops outputting the voltage VBL as the writing voltage VW.

The OR gate OR1 performs an OR logic operation on a signal S2 and the stop pulse STP to generate a signal S2a. A transistor M2 is then conducted or cut off according to the signal S2a. When the transistor M2 is conducted, the transmission gate TG1 may be cut off. The transistor M1 may pull down the writing voltage VW to a reference ground voltage VSS. Conversely, when the transmission gate TG1 is conducted, the transistor M1 may be cut off.

In this embodiment, when the transmission gate TG1 is conducted, the writing voltage generator 310 may cause the writing voltage VW to have a constant voltage level equal to a voltage value of voltage VBL. The writing voltage generator 310 may also cut off the transmission gate TG1 and conduct the transistor M1 according to the stop pulse STP, to pull down the writing voltage VW to the reference ground voltage VSS, and thereby adjust the pulse width of the writing voltage VW.

Incidentally, the voltage VBL may be provided by an external voltage regulator, without specific limitations. In this embodiment, the voltage VBL may have a constant voltage value.

In this embodiment, the reference voltage provider 320 may be a reference resistive memory cell array. The reference voltage provider 320 may have multiple reference resistive memory cells, with multiple resistive memory cells connected in parallel between a reference bit line REF_BL and a reference source polar line REF_SL, and respectively corresponding to the resistive memory cells among the resistive memory cell array 301. For example, a resistive memory cell SMC corresponds to a reference resistive memory cell RMC. When the resistive memory cell SMC is a selected resistive memory cell, the word line signal on the word line WLS of the resistive memory cell SMC may be activated, and the word line signal on the reference word line REF_WSL of the corresponding reference resistive memory cell RMC may also be synchronously activated.

Incidentally, in this embodiment, multiple switches may be respectively set between the reference resistive memory cells and a comparison circuit 320. Taking the reference resistive memory cell RMC as an example, the switch RSW may correspond to the reference resistive memory cell RMC. The switch RSW and the reference resistive memory cell RMC may be coupled to the same reference word line REF_WSL, and when the reference resistive memory cell RMC is activated, the switch RSW is synchronously conducted, thereby transmitting the reference voltage VREF generated according to the resistance value of the reference resistive memory cell RMC to the comparison circuit 320.

It is worth mentioning that, in this embodiment, the reference resistive memory cell and the corresponding resistive memory cell may synchronously perform the write operation, and synchronously change from the a resistance status LRS to a high resistance status HRS.

The comparison circuit 320 includes an amplifier 321, a comparator 322, and a pulse stopping generator 323. The amplifier 321 is configured to receive the reference voltage VREF, is activated according to a signal S3, generates an amplified voltage AVREF by amplifying the reference voltage VREF, and transmits the amplified voltage AVREF to the comparator 322. When in the low resistance status LRS, the reference resistive memory cell RMC may provide a relatively high reference voltage VREF, and the amplifier 321 may correspondingly provide an amplified voltage AVREF with a relatively high voltage value. When changing to the high resistance status HRS, the reference resistive memory cell RMC may provide a relatively low reference voltage VREF, and the amplifier 321 may correspondingly provide an amplified voltage AVREF with a relatively low voltage value.

The positive input terminal of the comparator 322 receives the target value TGV2, and the negative input terminal of the comparator 322 receives the amplified voltage AVREF. The comparator 322 generates the comparison result CR by comparing the target value TGV2 with the amplified voltage AVREF. When the reference resistive memory cell RMC is in the low resistance status LRS, the voltage value of the amplified voltage AVREF is greater than the target value TGV2, and the comparator 322 correspondingly generates a comparison result CR with a Boolean value of 0. Conversely, when the reference resistive memory cell RMC is in the high resistance status HRS, the voltage value of the amplified voltage AVREF is less than the target value TGV2, and the comparator 322 correspondingly generates a comparison result CR with a Boolean value of 1.

Incidentally, the target value TGV2 may be generated according to a band gap reference voltage generated by an external band gap voltage generator. The target value TGV2 may be set to half of the band gap reference voltage.

Further, the pulse stopping generator 323 is coupled to the output terminal of the comparator 322. The pulse stopping generator 323 is configured to generate the stop pulse STP correspondingly when the comparison result CR transitions from the Boolean value of 0 to the Boolean value of 1. In this embodiment, the pulse stopping generator 323 is coupled to the writing voltage generator 310 by the switch SW, and transmits the stop pulse STP to the writing voltage generator 310 when the switch SW is conducted according to a signal ROP. The switch SW may be conducted during the execution of the write operation. By the stop pulse STP, the writing voltage generator 310 may dynamically adjust the maintenance time of the writing voltage VW, maintaining the uniformity of the resistance value of the resistive memory cell after reset.

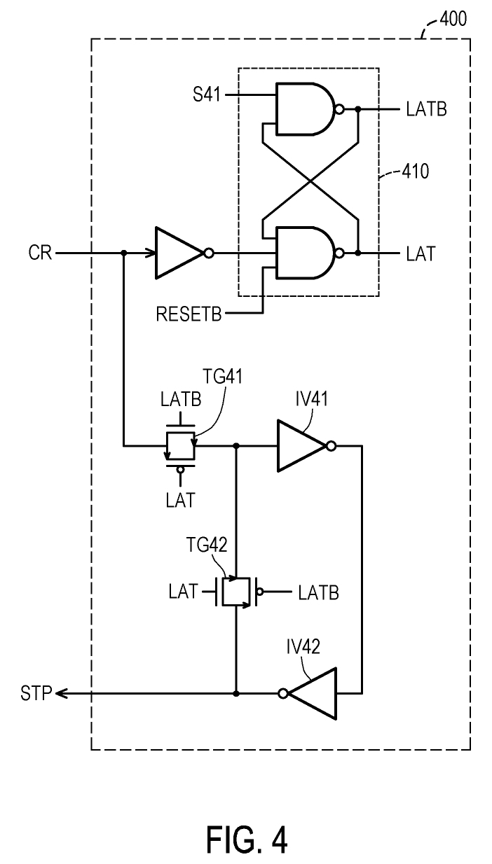

Referring to FIG. 4, FIG. 4 illustrates a circuit diagram of an implementation method of a pulse stopping generator according to an embodiment of the disclosure. A pulse stopping generator 400 includes a latch 410, transmission gates TG41 and TG42, and inverters IV41 and IV42. The latch 410 is an SR latch, and is configured to generate latch control signals LATB and LAT according to a reset signal RESETB, a signal S41, and the comparison result CR. The transmission gates TG41 and TG42 are conducted or disconnected according to the latch control signals LATB and LAT. When the comparison result CR is the Boolean value of 0, the transmission gate TG41 is conducted, while the transmission gate TG42 is disconnected. At this time, the inverters IV41 and IV42 are connected in series sequentially, and output a stop pulse STP with a Boolean value of 0. Conversely, when the comparison result CR changes to the Boolean value of 1, the transmission gate TG41 is disconnected, while the transmission gate TG42 is conducted. The inverters IV41 and IV42 are coupled to form a loop and constitute a latch. The inverters IV41 and IV42 latch the Boolean value of the comparison result CR (which is the Boolean value of 1), and continuously output a stop pulse STP with a Boolean value of 1.

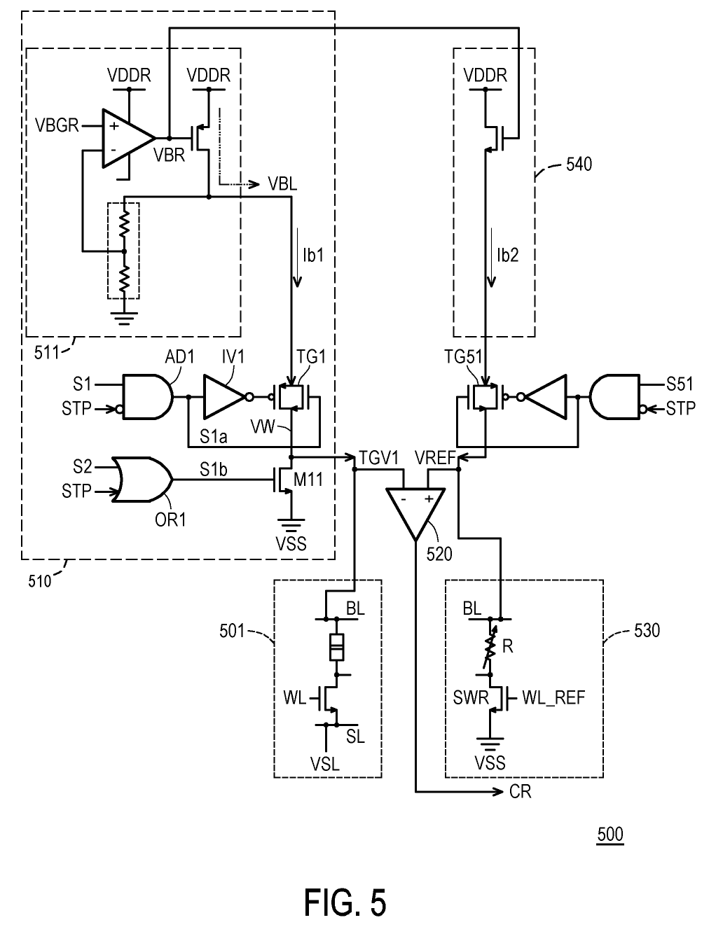

Referring to FIG. 5 below, FIG. 5 illustrates a schematic diagram of another embodiment of a writing circuit of the disclosure. A writing circuit 500 includes a writing voltage generator 510, a reference voltage provider 520, and a comparison circuit 530. The writing voltage generator 510 includes a voltage adjuster 511, an AND gate AD1, an OR gate OR1, an inverter IV1, a transmission gate TG1, and a transistor M1. The circuit coupling relationships and operations of the AND gate AD1, the OR gate OR1, the inverter IV1, the transmission gate TG1, and the transistor M1 are the same as in the embodiment of FIG. 3 and will not be explained in detail here. The voltage adjuster 511 may be a low drop out (LDO) voltage adjuster and may be configured to generate voltage VBL based on an operating voltage VDDR according to a reference voltage VBGR. The voltage adjuster 511 may be implemented by using any low drop out voltage adjustment circuit known to those skilled in the art, and the relevant details will not be explained in detail here.

The writing voltage generator 510 provides a writing voltage VW to the bit line BL of the resistive memory cell 501. The resistive memory cell 501 may be one of the resistive memory cells in a resistive memory cell array, which may be similar to the resistive memory cell array 301 in the embodiment of FIG. 3, and will not be elaborated further here.

In addition, the reference voltage provider 520 includes a resistor R and a switch SWR. The resistor R and the switch SWR are coupled in series between the reference bit line REF_BL and the reference ground voltage VSS. The switch SWR is a transistor switch, and is coupled to the reference word line REF_WSL. When the writing operation is performed, the switch SWR may be conducted, and the reference bit line REF_BL may receive a bias current Ib2. The reference voltage provider 520 may generate a reference voltage VREF on the reference bit line REF_BL according to the received bias current Ib2 and the resistance value provided by the resistor R.

The negative input terminal of the comparison circuit 520 is coupled to the bit line BL to receive the target value TGV1. The positive input terminal of the comparison circuit 520 is coupled to the reference bit line REF_BL to receive the reference voltage VREF. The comparison circuit 520 generates a comparison result CR by comparing the voltage levels of the target value TGV1 and the reference voltage VREF.

In this embodiment, the comparison result CR may be transmitted to the pulse stopping generator 400 as shown in FIG. 4, and cause the pulse stopping generator 400 to generate a stop pulse STP.

It is worth mentioning that the writing circuit 500 also includes a bias current generator 540. The bias current generator 540 is coupled to the reference bit line REF_BL through a transmission gate TG51. The transmission gate TG51 may be conducted according to the result of a logic operation performed on the signal S51 and the stop pulse STP. During the execution of the writing operation, the transmission gate TG51 may be conducted. The bias current generator 540 may provide the bias current Ib2 based on the operating voltage VDDR, according to a bias voltage VBR. Notably, the voltage adjuster 511 may also provide the bias current Ib1 based on the operating voltage VDDR, according to the bias voltage VBR. Therefore, in this embodiment, the bias currents Ib1 and Ib2 may be designed to have the same current value.

In another aspect, the resistor R may be a variable resistor. By adjusting the resistance value of the resistor R, the target resistance value of the resistive memory cell after reset may be adjusted.

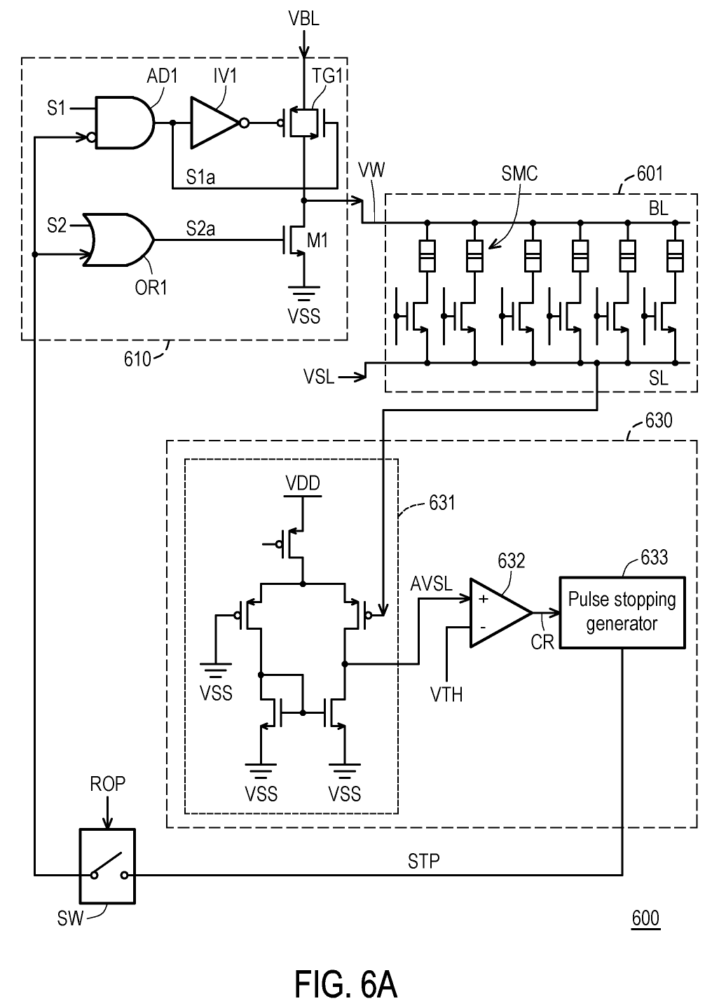

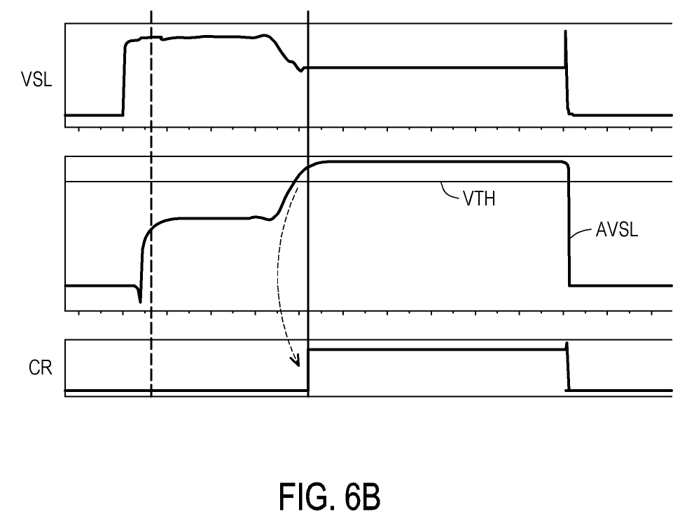

Referring to FIG. 6A and FIG. 6B, FIG. 6A illustrates a schematic diagram of another embodiment of a writing circuit of the disclosure, and FIG. 6B illustrates an action waveform diagram of the embodiment of FIG. 6A of the disclosure. In FIG. 6B, a vertical axis represents voltage, and a horizontal axis represents time. A writing circuit 600 includes a writing voltage generator 610 and a comparison circuit 630. The writing voltage generator 610 is similar to the writing voltage generator 610 in the embodiment of FIG. 3, which will not be elaborated further here. The writing voltage generator 610 is configured to provide a writing voltage VW to the bit line BL of the resistive memory cell array 601.

The comparison circuit 630 is coupled to the source line SL of the resistive memory cell array 601. The comparison circuit 630 generates a comparison result CR by comparing the voltage VSL on the source line SL of each resistive memory cell in the resistive memory cell array 601 with a threshold voltage VTH. In detail, the comparison circuit 630 includes an amplifier 631, a comparator 632, and a pulse stopping generator 633. In this embodiment, the amplifier 631 may be a differential amplifier, the relevant circuit details of which should be familiar to those skilled in the art and will not be elaborated further here. One input terminal of the amplifier 631 is coupled to the source line SL, and the other input terminal receives a reference ground voltage VSS. The amplifier 631 is configured to amplify the voltage VSL on the source line SL and generate an amplified voltage AVSL at the inverted output terminal thereof. In this embodiment, the threshold voltage VTH may be half of the operating voltage VDD.

The positive input terminal of the comparator 632 receives the amplified voltage AVSL, and the negative input terminal of the comparator 632 receives the threshold voltage VTH. The comparator 632 is configured to generate a comparison result CR by comparing the amplified voltage AVSL with the threshold voltage VTH. As shown in FIG. 6B, when a resistive memory cell in the resistive memory cell array 601 is selected to perform a write operation, when the selected resistive memory cell changes from a low resistance state (LRS) to a high resistance state (HRS), the voltage VSL on the source line SL may decrease from a relatively high voltage value to a relatively low voltage value. Correspondingly, the inverted amplified voltage AVSL generated by the amplifier 631 is relatively low for a resistive memory cell in the LRS state, and the amplified voltage AVSL is relatively high for a resistive memory cell in the HRS state. Therefore, when the resistive memory cell switches from the LRS state to the HRS state, the amplified voltage AVSL may change from being less than the threshold voltage VTH to being greater than the threshold voltage VTH. Accordingly, the comparator 632 may generate a comparison result CR transitions from the Boolean value of 0 to the Boolean value of 1 in response to the resistance switching action of the resistive memory cell.

The pulse stopping generator 633 is coupled to the output terminal of the comparator 632 and generates a stop pulse STP according to the comparison result CR produced by the comparator 632. The pulse stopping generator 633 may transmit the stop pulse STP to the writing voltage generator 610 by the switch SW according to the signal ROP, and may be configured to adjust the maintenance time of the writing voltage VW. When the comparison result CR transitions from the Boolean value of 0 to the Boolean value of 1, the pulse of the writing voltage VW may be terminated.

The pulse stopping generator 633 may be implemented by using the implementation method of FIG. 4, which will not be elaborated further here.

In summary, the writing circuit of the disclosure may dynamically adjust the maintenance time of the provided writing voltage according to the characteristics of the resistive memory cell selected to perform the write operation. Accordingly, the resistive memory cells among the resistive memory cell array may have substantially equal resistance values after reset, and the uniformity of their resistance values may be effectively improved. Moreover, by dynamically adjusting the maintenance time of the writing voltage, the phenomenon of excessive reset of the resistive memory cells can be effectively avoided, ensuring the operational performance of the resistive memory cells.

What is claimed is:

1. A writing circuit, comprising:
a writing voltage generator, providing a writing voltage to each of a plurality of resistive memory cells among a resistive memory cell array to perform a writing operation;
a reference voltage provider, generating and providing a reference voltage according to a resistance value of a reference element during the writing operation; and
a comparison circuit, generating a comparison result by comparing the reference voltage with a target value,
wherein the writing voltage generator adjusts a maintaining time of the writing voltage according to the comparison result.

2. The writing circuit according to claim 1, wherein the writing voltage generator comprises:
a plurality of reference resistive memory cells, wherein the plurality of reference resistive memory cells are arranged in a reference resistive memory cell array, the plurality of reference resistive memory cells respectively correspond to the plurality of resistive memory cells, and a reference word line signal of each of the plurality of reference memory cells is activated simultaneously with the word line signal of each corresponding resistive memory cell.

3. The writing circuit according to claim 1, wherein the writing voltage is a pulse voltage, the pulse voltage has a constant voltage level and a pulse width, and the writing voltage generator adjusts the maintaining time of the writing voltage by adjusting the pulse width according to the comparison result.

4. The writing circuit according to claim 1, wherein the comparison circuit is coupled to the reference voltage provider to receive the reference voltage, and a selected reference resistive memory cell of the plurality of reference resistive memory cells provides the reference voltage according to a resistance value of the selected reference resistive memory cell.

5. The writing circuit according to claim 1, wherein the comparison circuit comprises:
a comparator, comparing the reference voltage with the target value to generate the comparison result,
wherein the target value is generated according to a band gap reference voltage.

6. The writing circuit according to claim 5, wherein the target value is half of the band gap reference voltage.

7. The writing circuit according to claim 5, wherein the comparison circuit further comprises:
an amplifier, receiving the reference voltage, amplifying the reference voltage to generate an amplified voltage, and providing the amplified voltage to the comparator.

8. The writing circuit according to claim 5, wherein the comparison circuit further comprises:
a pulse stopping generator, coupled to the comparator, and generating a stop pulse according to the comparison result,
wherein the pulse stopping generator provides the stop pulse to the writing voltage generator, and the writing voltage generator stops providing the writing voltage according to the stop pulse.

9. The writing circuit according to claim 1, wherein the reference voltage provider comprises:
a resistor, providing the reference voltage according to the resistance value during the writing operation.

10. The writing circuit according to claim 9, wherein the resistor is a variable resistor.

11. The writing circuit according to claim 9, wherein the comparison circuit is coupled to the plurality of resistive memory cells, and receives the target value from a bit line of a selected resistive memory cell.

12. The writing circuit according to claim 11, wherein the comparison circuit comprises:
a comparator, generating the comparison result by comparing the reference voltage with the target value.

13. The writing circuit according to claim 11, wherein the resistor and the selected resistive memory cell receive bias currents having the same current value.

14. The writing circuit according to claim 11, wherein the writing voltage generator provides the writing voltage to the bit line of the selected resistive memory cell during the writing operation.

15. The writing circuit according to claim 1, wherein the writing operation is a reset operation.

16. A writing circuit, comprising:
a writing voltage generator, providing a writing voltage to each of a plurality of resistive memory cells among a resistive memory cell array to perform a writing operation; and
a comparison circuit, generating a comparison result by comparing a voltage on a source line of each of the plurality of resistive memory cells with a threshold voltage,
wherein the writing voltage generator adjusts a maintaining time of the writing voltage according to the comparison result.

17. The writing circuit according to claim 16, wherein the writing voltage is a pulse voltage, the pulse voltage has a constant voltage level and a pulse width, and the writing voltage generator adjusts the maintaining time of the writing voltage by adjusting the pulse width according to the comparison result.

18. The writing circuit according to claim 16, wherein the comparison circuit comprises:
a comparator, having a first terminal coupled to the source line of each of the plurality of resistive memory cells to receive a target value, and comparing the target value with the threshold voltage to generate the comparison result,
wherein the threshold voltage is generated according to an operating voltage of the resistive memory cell array.

19. The writing circuit according to claim 18, further comprising:
an amplifier, coupled between the comparator and the resistive memory cell array, generating an amplified voltage according to the target value, and providing the amplified voltage to the comparator.

20. The writing circuit according to claim 18, wherein the comparison circuit further comprises:
a pulse stopping generator, coupled to the comparator, and generating a stop pulse according to the comparison result,
wherein the pulse stopping generator provides the stop pulse to the writing voltage generator, and the writing voltage generator stops providing the writing voltage according to the stop pulse.
